(19) United States
(12) Patent Application Publication
(10) Pub. No.: US 2025/0231645 A1
(43) Pub. Date: Jul. 17, 2025

(54) DISPLAY DEVICE AND METHOD FOR OPERATING SAME

(71) Applicants: SAMSUNG ELECTRONICS CO., LTD., Suwon-si (KR); RESEARCH & BUSINESS FOUNDATION SUNGKYUNKWAN UNIVERSITY, Suwon-si (KR)

(72) Inventors: Kwangdon KIM, Suwon-si (KR); Byeungwoo JEON, Suwon-si (KR); Jaelin LEE, Suwon-si (KR); Muho CHEON, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 19/170,837

(22) Filed: Apr. 4, 2025

Related U.S. Application Data
(63) Continuation of application No. PCT/KR2023/012060, filed on Aug. 14, 2023.

(30) Foreign Application Priority Data
Oct. 7, 2022 (KR) 10-2022-0129043

(51) Int. Cl. G06F 3/042; G06F 3/044

(52) U.S. Cl. CPC G06F 3/042; G06F 3/0447; G06F 2203/04105

(57) ABSTRACT

A display device includes: a display panel including a plurality of pixels; a memory storing one or more instructions; and one or more processors configured to execute the one or more instructions to: change light emission patterns of pixels included in a contact area at which an object contacts the display panel, measure a first reflection pattern at the contact area according to the changed light emission patterns, detect a surface roughness of the object based on the first reflection pattern, estimate a degree of deformation of a transparent layer of the display panel corresponding to the contact between the display panel and the object, measure a second reflection pattern at the contact area, based on the degree of deformation of the transparent layer, and detect a hardness of the object based on the second reflection pattern.

### CROSS-REFERENCE TO RELATED APPLICATION(S)

This application is a continuation of International Application No. PCT/KR2023/012060, filed on Aug. 14, 2023, in the Korean Intellectual Property Receiving Office, which is based on and claims priority to Korean Patent Application No. 10-2022-0129043, filed on Oct. 7, 2022, in the Korean Intellectual Property Office, the disclosures of which are incorporated by reference herein in their entireties.

### BACKGROUND

### 1. Field

This disclosure relates to a display device, and more particularly, to a display device for detecting tactile information, and a method of operating the display device.

### 2. Description of Related Art

Recently, the importance of display devices has been increasing with the development of multimedia. In particular, with the development of wireless network technology, display devices serve as image display devices for sharing various pieces of information (e.g., tactile information) sensed from a user or a user device with a counterpart, and various types of display devices, such as organic light-emitting diode (OLED) devices or liquid-crystal display (LCD) devices, have been developed.

However, related-art display devices have technical limitations in that they are able to sense only a limited range of tactile information about an object that is in contact with a display panel, by using a particular sensor (e.g., a capacitive sensor or an ultrasonic sensor).

Accordingly, there is a need for a display device capable of detecting various types of tactile information about an object that is in contact with a display device, while performing an image display function.

### SUMMARY

Aspects will be set forth in part in the description which follows and, in part, will be apparent from the description, or may be learned by practice of the presented embodiments.

According to an aspect of the disclosure, a display device may include: a display panel including a plurality of pixels; a memory storing one or more instructions; and one or more processors configured to execute the one or more instructions to: change light emission patterns of pixels included in a contact area at which an object contacts the display panel, measure a first reflection pattern at the contact area according to the changed light emission patterns, detect a surface roughness of the object based on the first reflection pattern, estimate a degree of deformation of a transparent layer of the display panel corresponding to the contact between the display panel and the object, measure a second reflection pattern at the contact area, based on the degree of deformation of the transparent layer, and detect a hardness of the object based on the second reflection pattern.

The one or more processors may be further configured to execute the one or more instructions to: based on an amount of light received in at least one sub-region of the display panel being less than a threshold value, identify the at least one sub-region of the display panel as the contact area at which the object contacts the display panel.

The one or more processors may be further configured to execute the one or more instructions to: determine the light emission patterns based on at least one of a difference in wavelength between lights emitted from the pixels included in the contact area, a reflectivity of the transparent layer, or a resolution to measure the surface roughness.

The changing the light emission patterns may include: changing at least one of a type of a light emission color, a light emission shape, a light emission period, or a light emission direction of the pixels included in the contact area.

The one or more processors may be further configured to execute the one or more instructions to: measure a deformation time period of the transparent layer and a deformation recovery time period of the transparent layer, and estimate the degree of deformation of the transparent layer based on the measured deformation time period of the transparent layer, the measured deformation recovery time period of the transparent layer, and a deformation of the transparent layer over time.

The display panel may include a light-receiving layer, a light-emitting layer, and the transparent layer stacked in a vertical direction, where the light-receiving layer includes a photodetector configured to measure the first reflection pattern or the second reflection pattern, and where the light-emitting layer is provided on the light-receiving layer and includes the plurality of pixels.

The transparent layer may be provided on the light-emitting layer and include an elastic material.

A region for detection of the surface roughness and a region for detection of the hardness may overlap in at least one region among the plurality of pixels.

According to an aspect of the disclosure, a method of operating a display device may include: changing light emission patterns of pixels included in a contact area at which an object contacts a display panel of the display device, the display panel including a plurality of pixels; measuring a first reflection pattern at the contact area according to the changed light emission patterns; detecting a surface roughness of the object based on the first reflection pattern; estimating a degree of deformation of a transparent layer of the display panel corresponding to the contact between the display panel and the object; measuring a second reflection pattern at the contact area, based on the degree of deformation of the transparent layer; and detecting a hardness of the object based on the second reflection pattern.

The method may further include: based on an amount of light received in at least one sub-region of the display panel being less than a threshold value, identifying the at least one sub-region of the display panel as the contact area at which the object contacts the display panel.

The method may further include: determining the light emission patterns based on at least one of a difference in wavelength between lights emitted from the pixels included in the contact area, a reflectivity of the transparent layer, or a resolution to measure the surface roughness.

The changing the light emission patterns may include: changing at least one of a type of a light emission color, a light emission shape, a light emission period, or a light emission direction of the pixels included in the contact area.

The method may further include: measuring a deformation time period of the transparent layer and a deformation recovery time period of the transparent layer, and estimating the degree of deformation of the transparent layer based on the measured deformation time period of the transparent layer, the measured deformation recovery time period of the transparent layer, and a deformation of the transparent layer over time.

The display panel may include a light-receiving layer, a light-emitting layer, and the transparent layer that are stacked in a vertical direction, where the light-receiving layer includes a photodetector configured to measure the first reflection pattern or the second reflection pattern, where the light-emitting layer is provided on the light-receiving layer and includes the plurality of pixels, and where the transparent layer is provided on the light-emitting layer and includes an elastic material.

A region for detection of the surface roughness and a region for detection of the hardness may overlap in at least one region among the plurality of pixels.

A computer-readable recording medium having recorded thereon a program for causing a computer to execute a method, the method may include: changing light emission patterns of pixels included in a contact area at which an object contacts a display panel of the display device, the display panel including a plurality of pixels; measuring a first reflection pattern at the contact area according to the changed light emission patterns; detecting a surface roughness of the object based on the first reflection pattern; estimating a degree of deformation of a transparent layer of the display panel corresponding to the contact between the display panel and the object; measuring a second reflection pattern at the contact area, based on the degree of deformation of the transparent layer; and detecting a hardness of the object based on the second reflection pattern.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating a display device according to an embodiment;

FIG. 2 is a schematic plan view illustrating a display device according to an embodiment;

FIG. 3A illustrates an enlarged view of pixels within a display device, according to an embodiment;

FIG. 3B illustrates a region for detection of tactile information according to an embodiment;

FIG. 3C illustrates a region for detection of tactile information according to another embodiment;

FIG. 4 illustrates a structure of a display panel according to an embodiment;

FIG. 5 illustrates a method of operating a display device, according to an embodiment;

FIG. 6 illustrates a method of operating a display device, according to an embodiment;

FIG. 7 is a diagram illustrating an operation of changing a light emission pattern, according to an embodiment;

FIG. 8 is a diagram illustrating an operation of estimating a degree of deformation of a display panel, according to an embodiment;

FIG. 9 is a block diagram illustrating an electronic device including a processor, according to an embodiment; and

FIG. 10 is a block diagram illustrating an electronic device including a display module, according to an embodiment.

### DETAILED DESCRIPTION

The terms used herein will be briefly described, and then the present disclosure will be described in detail.

Although the terms used herein are selected from among common terms that are currently widely used in consideration of their functions in the present disclosure, the terms may be different according to an intention of one of ordinary skill in the art, a precedent, or the advent of new technology. Also, in particular cases, the terms may be discretionally selected by the applicant of the present disclosure, in which case, the meaning of those terms will be described in detail in the corresponding part of the detailed description. Therefore, the terms used herein are not merely designations of the terms, but the terms are defined based on the meaning of the terms and content throughout the present disclosure.

Throughout the present specification, when a part “includes”, “has”, or “comprises” a component, it means that the part may additionally include other components rather than excluding other components as long as there is no particular opposing recitation. In addition, as used herein, the terms such as “ . . . er (or)”, “ . . . unit”, “ . . . module”, etc., denote a unit that performs at least one function or operation, which may be implemented as hardware or software or a combination thereof.

Hereinafter, embodiments will be described with reference to the accompanying drawings in such a manner that the embodiments may be easily carried out by those of skill in the art. The present disclosure may, however, be embodied in many different forms and should not be construed as being limited to an embodiment set forth herein. In order to clearly describe the present disclosure, portions that are not relevant to the description of the present disclosure are omitted in the drawings, and similar reference numerals are assigned to similar elements throughout the present specification.

In the embodiments of the present specification, the term “user” may refer to a person who controls systems, functions, or operations, and may include a developer, an administrator, or an installer.

In addition, in the embodiments of the present specification, the term ‘image’ or ‘picture’ may refer to a still image, a moving image consisting of a plurality of continuous still images (or frames), or a video.

In the embodiments of the present specification, the term “pixel” may refer to the minimum unit that constitutes an image displayed on a display device, and may include a light-emitting diode (LED), an organic LED (OLED), and an active-matrix OLED (AMOLED).

In the embodiments of the present specification, the term “sub-pixel region” may refer to a region including a red sub-pixel, a green sub-pixel, and a blue sub-pixel.

In the embodiments of the present specification, the expression “empty space within a pixel” may refer to the other region within the pixel than a sub-pixel region.

In the embodiments of the present specification, the term “tactile information” may include information about the surface roughness or hardness of an object.

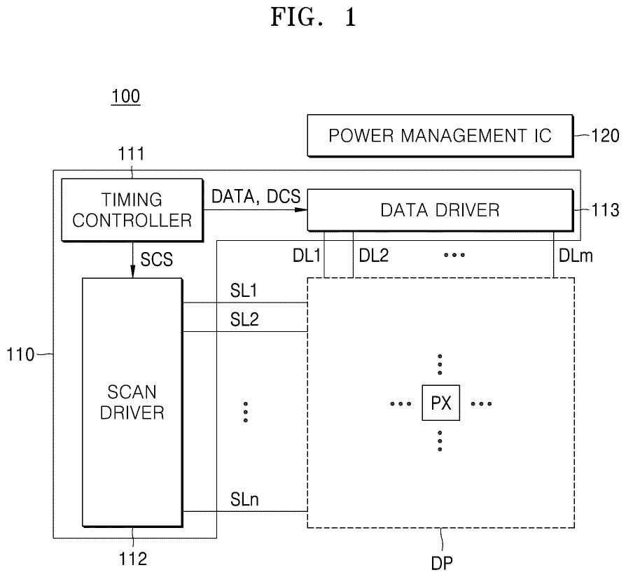

FIG. 1 is a block diagram illustrating a display device according to an embodiment.

Referring to FIG. 1, a display device 100 according to an embodiment of the present disclosure may include a display panel DP including a plurality of pixels PX, a timing controller 111, a scan driver 112, a data driver 113, and a power management integrated circuit (IC) (PMIC) 120.

In an embodiment, the timing controller 111 may provide the data driver 113 with a data value DATA, a data control signal DCS, and the like for each frame.

In an embodiment, the timing controller 111 may provide the scan driver 112 with a clock signal, a scan control signal SCS, and the like.

In an embodiment, the data driver 113 may generate data voltages to be provided to the data lines DL1, DL2, . . . , DLm, by using the data value DATA and the data control signal DCS both received from the timing controller 111. Here, m is a natural number.

In an embodiment, the scan driver 112 may receive the scan control signal SCS (including a clock signal, a scan start signal, and the like) from the timing controller 111, and generate scan signals to be provided to scan lines SL1, SL2, . . . , SLn. Here, n is a natural number.

In an embodiment, the display panel DP may include a light-receiving layer, a light-emitting layer, and a transparent layer that are stacked in a vertical direction. Here, the light-receiving layer may include at least one photodetector configured to measure a reflection pattern, and the light-emitting layer may be arranged on the light-receiving layer to include the plurality of pixels PX. The transparent layer may be arranged on the light-emitting layer in the display panel DP and may be made of an elastic material.

In an embodiment, the display panel DP includes a plurality of pixels (e.g., a plurality of self-light-emitting elements) PX. The plurality of pixels PX may be connected to corresponding data lines and scan lines, respectively.

In an embodiment, each of the plurality of pixels PX may be a red pixel that emits red light, a blue pixel that emits blue light, or a green pixel that emits green light. In another example, the plurality of pixels PX may include white, cyan, magenta, and yellow pixels, instead of red, green, and blue pixels.

In the present specification, a circuit including at least one of the timing controller 111, the scan driver 112, and the data driver 113 may be referred to as a display driver IC (DDI) 110.

In an embodiment, the DDI 110 may be provided in the form of an IC.

In an embodiment, the PMIC 120 may receive external power (e.g., battery voltage). In an example, the PMIC 120 may generate a voltage to be supplied to the DDI 110, based on the external input voltage.

In an embodiment, the PMIC 120 may generate a voltage to be provided to the timing controller 111 of the DDI 110.

In an embodiment, the PMIC 120 may include at least one regulator. In an example, the at least one regulator may generate output voltages having various voltage levels, from a voltage supplied from an external power source. In an example, the at least one regulator may be implemented as a controller or may be arranged within a controller. In an example, the at least one regulator may include, but is not limited to, a buck converter. For example, the at least one regulator may include at least one of a buck-boost converter, a boost converter, or a Ćuk converter.

A device and a method according to embodiments of the present disclosure may provide a display device capable of detecting the surface roughness or hardness of an object and also having an image display function, and a method of operating the display device.

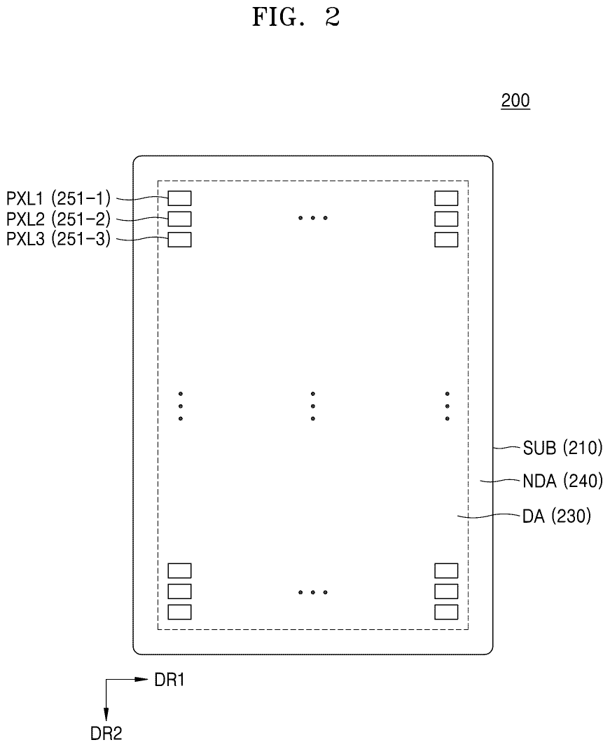

FIG. 2 is a schematic plan view 200 illustrating a display device according to an embodiment.

Referring to FIG. 2, the display device may include a driving unit configured to drive pixels PXL1, PXL2, and PXL3 (251-1, 251-2, and 251-3), which are provided on a substrate SUB (210) and each include at least one light-emitting element, and a wiring unit that connects the driving unit to the pixels PXL1, PXL2, and PXL3 (251-1, 251-2, and 251-3).

In an embodiment, the substrate SUB (210) may include a display area DA (230) and a non-display area NDA (240).

In an embodiment, the display area DA (230) may be an area in which pixels PXL1, PXL2, and PXL3 (251-1, 251-2, and 251-3) that display an image are provided. The non-display area NDA (240) may be an area in which the driving unit for driving the pixels PXL1, PXL2, and PXL3 (251-1, 251-2, and 251-3), and a portion of the wiring unit connecting the pixels PXL1, PXL2, and PXL3 (251-1, 251-2, and 251-3) to the driving unit are provided.

In an embodiment, the surface of the display area DA (230) may include a transparent layer that is made of an elastic material, to detect the hardness of an object that is in contact with the display device.

In an embodiment, the non-display area NDA (240) may be positioned adjacent to the display area DA (230). The non-display area NDA (240) may be provided on at least one side of the display area DA (230). For example, the non-display area NDA (240) may surround the perimeter (or edges) of the display area DA (230).

In an embodiment, the wiring unit may electrically connect the driving unit to the pixels PXL1, PXL2, and PXL3 (251-1, 251-2, and 251-3). The wiring unit may provide signals to the pixels PXL1, PXL2, and PXL3 (251-1, 251-2, and 251-3) and may include fan-out lines connected to signal lines that are connected to each of the pixels PXL1, PXL2, and PXL3 (251-1, 251-2, and 251-3), for example, scan lines, data lines, emission control lines, etc.

In an embodiment, the substrate SUB (210) may include a transparent insulating material to enable light transmission. The substrate SUB (210) may be a rigid substrate or a flexible substrate.

In an embodiment, the pixels PXL1, PXL2, and PXL3 (251-1, 251-2, and 251-3) may include a first pixel PXL1, a second pixel PXL2, and a third pixel PXL3.

In an example, the first pixel PXL1 may be a red pixel, the second pixel PXL2 may be a green pixel, and the third pixel PXL3 may be a blue pixel. However, the present disclosure is not limited thereto, and the pixels PXL1, PXL2, and PXL3 (251-1, 251-2, and 251-3) may emit light in other colors than red, green, and blue, respectively.

In an embodiment, the first pixel PXL1 (251-1), the second pixel PXL2 (251-2), and the third pixel PXL3 (251-3) may be sequentially arranged in a second direction DR2.

In an embodiment, each of the pixels PXL1, PXL2, and PXL3 (251-1, 251-2, and 251-3) may include at least one light-emitting element (e.g., a sub-pixel) that is driven by a corresponding scan signal and data signal. The light-emitting elements may have a size as small as nanoscale (or nanometer) or microscale (or micrometer), and may be connected in parallel to other light-emitting elements arranged adjacent thereto, but are not limited thereto. Each of the pixels PXL1, PXL2, and PXL3 (251-1, 251-2, and 251-3) may configure a light source, and the display device may detect the surface roughness and/or hardness of an object that is in contact with the display panel by measuring a reflection pattern according to the changed light emission patterns of the pixels.

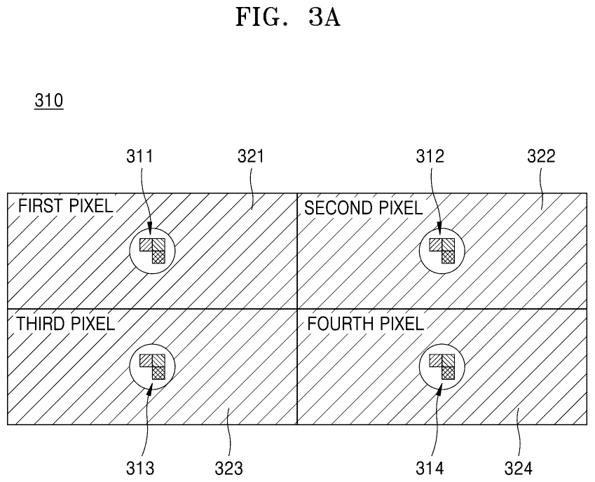

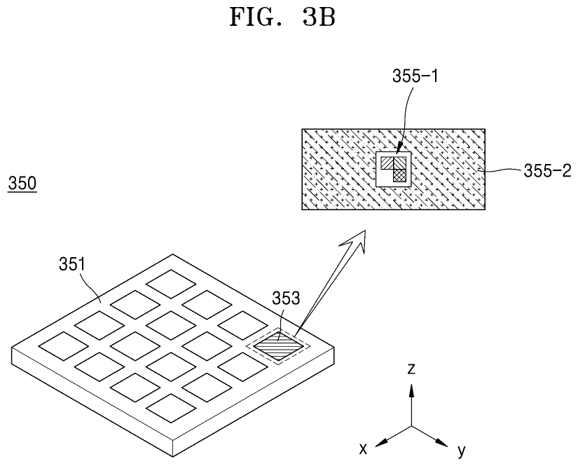

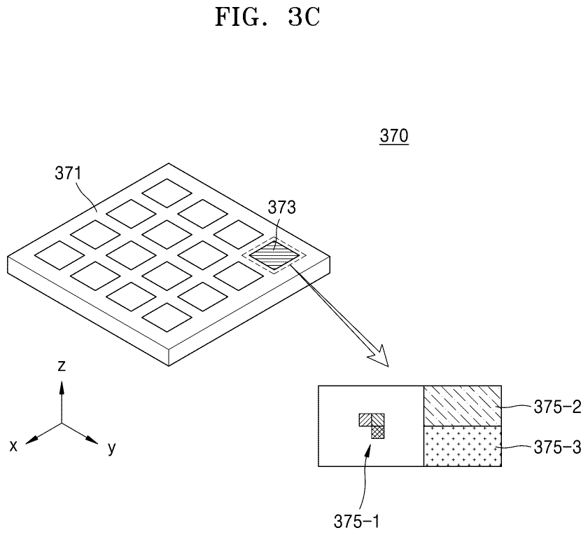

FIG. 3A illustrates an enlarged view 310 of pixels included in a display panel, according to an embodiment.

In detail, FIG. 3A illustrates an enlarged view of pixels included in the display panel of the display device 100 of FIG. 1.

In the embodiments of the present specification, the term “sub-pixel region” may refer to a region including a red sub-pixel, a green sub-pixel, and a blue sub-pixel. In the embodiments of the present specification, the expression “empty space within a pixel” may refer to the other region within the pixel than a sub-pixel region.

Referring to FIG. 3A, the display panel of the display device may include a first pixel to a fourth pixel.

In an embodiment, the first pixel may include a first sub-pixel region 311 and a first region 321, which is an empty space within the first pixel. The second pixel may include a second sub-pixel region 312 and a second region 322, which is an empty space within the second pixel. The third pixel may include a third sub-pixel region 313 and a third region 323, which is an empty space within the third pixel. The fourth pixel may include a fourth sub-pixel region 314 and a fourth region 324, which is an empty space within the fourth pixel.

The display device according to an embodiment of the present disclosure may detect the surface roughness and/or hardness of an object that is in contact with the display panel, based on the first region 321 to the fourth region 324 of the display panel. A region for detection of surface roughness and a region for detection of hardness will be described in detail below with reference to FIG. 3B.

In the description provided above with reference to FIG. 3A, the display panel is described as including the first pixel to the fourth pixel, but the present disclosure is not limited thereto, and the number of pixels included in the display panel of the display device according to an embodiment of the present disclosure may be changed depending on the manufacturing purpose or manufacturing method of the device.

FIG. 3B illustrates a region for detection of tactile information according to an embodiment.

In detail, FIG. 3B illustrates a region for detection of tactile information about an object in the display panel of the display device 100 of FIG. 1.

FIG. 3B is a plan view 350 of a pixel region 353 corresponding to one pixel in a display panel 351 including a plurality of pixels, as viewed in the z-axis direction. Here, the pixel region may refer to a region allocated to one pixel in the display panel, to perform the function of a pixel.

In an embodiment, the pixel region 353 may include a first sub-region 355-1 and a second sub-region 355-2.

In an embodiment, the first sub-region 355-1 may include a region provided with at least one sub-pixel (e.g., at least one of a red sub-pixel, a green sub-pixel, or a blue sub-pixel) included in the pixel, and emits light by using the at least one sub-pixel.

In an embodiment, the second sub-region 355-2 may be a region of the pixel region that does not overlap with the first sub-region 355-1, and may include a region for detecting the surface roughness and/or hardness of an object that is in contact with the display panel.

In an embodiment, a region for detection of the surface roughness of an object, and a region for detection of the hardness of an object may overlap with each other in at least one region included in the second sub-region 355-2.

According to an embodiment of the present disclosure, the display device includes a region for detection of the surface roughness of an object and a region for detection of the hardness of an object, which overlap with each other in an empty space of a pixel region within the display panel (e.g., the second sub-region 355-2 within the pixel region), and thus has an additional function of detecting tactile information about an object that is in contact with the display panel, while maintaining the form and image expression function of related-art display devices.

FIG. 3C illustrates a region for detection of tactile information according to another embodiment.

In detail, FIG. 3C illustrates a region for detection of tactile information about an object in the display panel of the display device 100 of FIG. 1.

FIG. 3C is a plan view 370 of a pixel region 373 corresponding to one pixel in a display panel 371 including a plurality of pixels, as viewed in the z-axis direction. Here, the pixel region may refer to a region allocated to one pixel in the display panel, to perform the function of a pixel.

In an embodiment, the pixel region 373 may include a first sub-region 375-1, a second sub-region 375-2, and a third sub-region 375-3.

In an embodiment, the first sub-region 375-1 may include a region provided with at least one sub-pixel (e.g., at least one of a red sub-pixel, a green sub-pixel, or a blue sub-pixel) included in the pixel, and emits light by using the at least one sub-pixel.

In an embodiment, the second sub-region 375-2 may be a region of the pixel region that does not overlap with the first sub-region 375-1 and the third sub-region 375-3, and may include a region for detecting the surface roughness of an object that is in contact with the display panel.

In an embodiment, the third sub-region 375-3 may be a region of the pixel region that does not overlap with the first sub-region 375-1 and the second sub-region 375-2, and may include a region for detecting the hardness of an object that is in contact with the display panel.

In an embodiment, the region for detection of the surface roughness of an object, and the region for detection of the hardness of an object may include different regions in the second sub-region of the display panel.

According to an embodiment of the present disclosure, the display device includes a region for detection of the surface roughness of an object and a region for detection of the hardness of an object in respective empty spaces of a pixel region within the display panel (e.g., the second sub-region 375-2 and the third sub-region 375-3 within the pixel region), and thus has an additional function of detecting tactile information about an object that is in contact with the display panel, while maintaining the form and image expression function of related-art display devices.

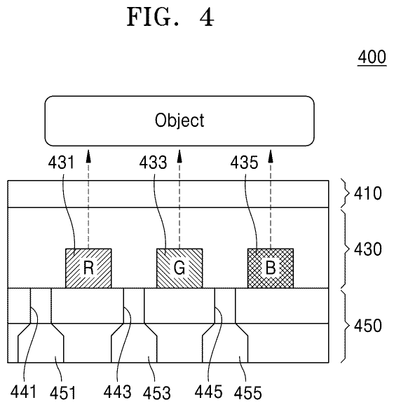

FIG. 4 illustrates a structure of a display panel according to an embodiment.

In detail, FIG. 4 illustrates a structure 400 of the display panel of the display device 100 of FIG. 1.

Referring to FIG. 4, the display panel may include a transparent layer 410, a light-emitting layer 430, and a light-receiving layer 450 that are stacked in a vertical direction.

In an embodiment, the transparent layer 410 may be arranged on the light-emitting layer 430 of the display panel and may be implemented with an elastic material (e.g., an elastomer).

In an embodiment, the shape of the transparent layer 410 may be deformed due to contact between the display panel and an object, and a reflection pattern of light emitted from a plurality of pixels (e.g., 431, 433, and 435) of the light-emitting layer 430 may be changed based on the deformed shape or degree of deformation of the transparent layer 410.

In an embodiment, the light-emitting layer 430 may be arranged on the light-receiving layer 450 of the display panel and may include a plurality of pixels (e.g., a first pixel 431, a second pixel 433, and a third pixel 435).

In an embodiment, when contact occurs between the display panel and an object, a processor may identify pixels included in a contact area between the display panel and the object from among the plurality of pixels included in the light-emitting layer 430 (e.g., the first pixel 431, the second pixel 433, and the third pixel 435).

In an embodiment, a light emission pattern of the light-emitting layer 430 may be changed based on at least one of a difference in wavelength between lights emitted from the pixels included in the contact area (e.g., the first pixel 431, the second pixel 433, and the third pixel 435), the reflectivity of the transparent layer of the display panel, or a resolution required for measuring surface roughness.

In an embodiment, the processor may change the light emission pattern by changing the type of a light emission color (e.g., red (R), green (G), or blue (B)), a light emission shape, a light emission period, and a light emission direction of the pixels (e.g., the first pixel 431, the second pixel 433, and the third pixel 435) of the light-emitting layer 430 included in the contact area between the display panel and the object.

In an embodiment, the light-receiving layer 450 may include a first photodetector 451, a second photodetector 453, and a third photodetector 455. Here, the first photodetector 451, the second photodetector 453, and the third photodetector 455 of the light-receiving layer 450 may be arranged at positions that do not overlap with the pixels of the light-emitting layer 430 (e.g., the first pixel 431, the second pixel 433, and the third pixel 435).

In an embodiment, the first photodetector 451, the second photodetector 453, and the third photodetector 455 may measure reflection patterns of lights emitted from the pixels and then reflected from the contact surface with the object.

For example, the first photodetector 451 included in the light-receiving layer 450 may measure, through a first passage 441, reflection patterns of lights emitted from the plurality of pixels (e.g., 431, 433, and 435) of the light-emitting layer 430, and reflected from the contact surface with the object. Here, the first passage 441 may refer to a passage connecting the light-emitting layer 430 to the light-receiving layer 450 and allowing the first photodetector 451 to measure a reflection pattern (or reflected light).

For example, the second photodetector 453 included in the light-receiving layer 450 may measure, through a second passage 443, reflection patterns of lights emitted from the plurality of pixels (e.g., 431, 433, and 435) of the light-emitting layer 430, and reflected from the contact surface with the object. Here, the second passage 443 may refer to a passage connecting the light-emitting layer 430 to the light-receiving layer 450 and allowing the second photodetector 453 to measure a reflection pattern (or reflected light).

For example, the third photodetector 455 included in the light-receiving layer 450 may measure, through a third passage 445, reflection patterns of lights emitted from the plurality of pixels (e.g., 431, 433, and 435) of the light-emitting layer 430, and reflected from the contact surface with the object. Here, the third passage 445 may refer to a passage connecting the light-emitting layer 430 to the light-receiving layer 450 and allowing the third photodetector 455 to measure a reflection pattern (or reflected light).

In an embodiment, the processor may identify a contact area between a surface layer of the display panel (e.g., the transparent layer 410) and an object, based on the amount of received light that is measured by the light-receiving layer 450.

In an embodiment, the processor may detect the surface roughness or hardness of the object that is in contact with the surface layer of the display panel (e.g., the transparent layer 410), based on the reflection pattern measured by the light-receiving layer 450.

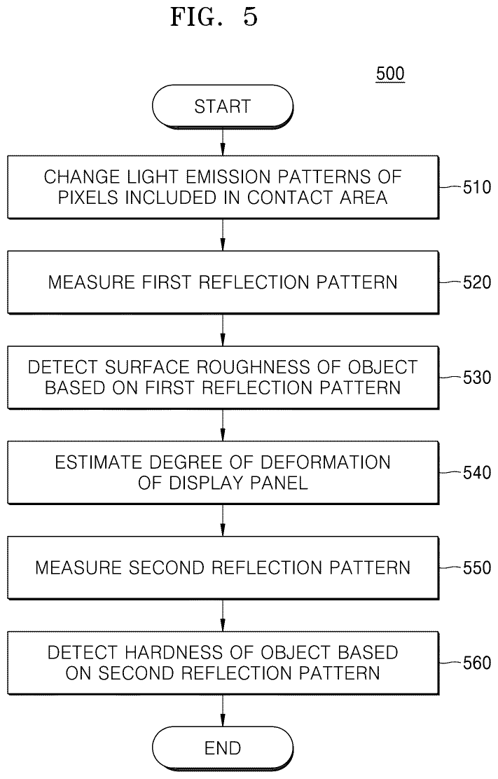

FIG. 5 illustrates a method of operating a display device, according to an embodiment.

In detail, FIG. 5 a diagram 500 for describing an operation of changing a light emission pattern at a contact surface with an object, and an operation of detecting the surface roughness of the object based on the changed light emission pattern, which are performed by the display device 100 of FIG. 1.

Referring to FIG. 5, the operation of changing the light emission pattern and detecting the surface roughness, which are performed by the processor of the display device may include operations 510, 520, 530, 540, and 550.

In operation 510, the processor may change light emission patterns of pixels included in the contact area.

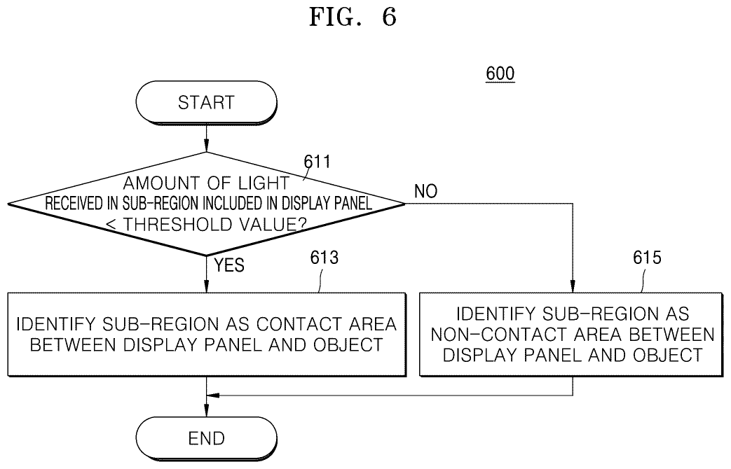

In an embodiment, when a contact area between an object and the display panel is detected, the processor may change light emission patterns of pixels included in the light-emitting layer of the display panel to predetermined light emission patterns (e.g., light emission patterns for measuring the surface roughness of an object). The operation of detecting a contact area by an object will be described below with reference to FIG. 6.

In an embodiment, the processor may change the light emission patterns based on at least one of a difference in wavelength between lights emitted from the pixels included in the contact area, the reflectivity of the transparent layer of the display panel, or a resolution required to measure surface roughness.

In an embodiment, the processor may change the light emission patterns by changing the type of a light emission color, a light emission shape, a light emission period, and a light emission direction of the pixels included in the contact area between the display panel and the object.

In an embodiment, the processor may change the light emission patterns such that a first region of the contact area emits red light and a second region emits green light.

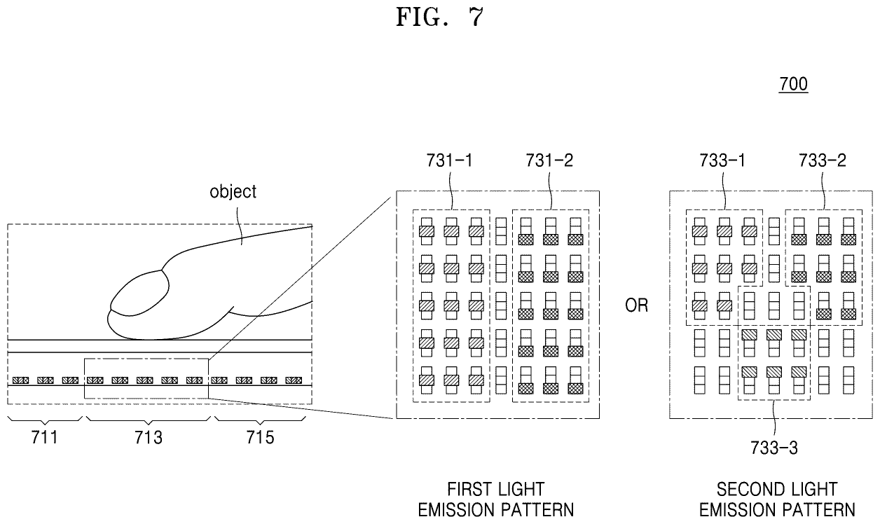

In an embodiment, the processor may change the light emission patterns such that a first region of the contact area emits red light, a second region emits green light, and a third region emits blue light, and then the light emission color of each region is changed according to a predetermined time. The operation of changing the light emission patterns for measuring the surface roughness of an object will be described below with reference to FIG. 7.

In operation 520, the processor may measure a first reflection pattern.

In an embodiment, the processor may measure a first reflection pattern of light emitted from the pixels included in the contact area, and then reflected from the contact surface with the object, based on the changed light emission patterns.

In operation 530, the processor may detect the surface roughness of the object based on the first reflection pattern.

In an embodiment, the processor may obtain a surface roughness value of the object that is in contact with the display surface, by inputting the measured first reflection pattern into a predetermined algorithm to calculate the surface roughness value corresponding to the first reflection pattern.

In an embodiment, the processor may obtain a surface roughness value of the object that is in contact with the display surface, by retrieving data corresponding to the measured first reflection pattern from a database to identify the surface roughness value that matches the first reflection pattern. Here, the surface roughness value may be stored in the database in association with data corresponding to the first reflection pattern.

In operation 540, the processor may estimate a degree of deformation of the display panel.

In an embodiment, the processor may measure a deformation time period of the transparent layer of the display panel, a deformation recovery time period of the transparent layer, and a deformation over time. Here, the deformation time period of the transparent layer may refer to the time period from the start of the contact between the display panel and the object to the time point at which the object may no longer be compressed due to the contact. The deformation recovery time period of the transparent layer may refer to the time period from the time point at which the object may no longer be compressed due to the contact between the display panel and the object, to the time point at which the object recovers its original state.

In an embodiment, the processor may estimate the degree of deformation (e.g., a deformation indentation or a deformation area) of the transparent layer caused by the contact between the display panel and the object, based on the deformation time period, the deformation recovery time period, and the deformation over time of the transparent layer.

In operation 550, the processor may measure a second reflection pattern.

In an embodiment, the processor may measure the second reflection pattern of light emitted from the pixels included in the contact area and then reflected from the contact surface with the object, based on the degree of deformation (e.g., a deformation indentation, or a deformation area) of the transparent layer of the display panel.

In operation 560, the processor may detect the hardness of the object based on the second reflection pattern.

In an embodiment, the processor may obtain a hardness value of the object that is in contact with the display surface, by inputting the measured first reflection pattern into a predetermined algorithm to calculate the surface roughness value corresponding to the second reflection pattern.

In an embodiment, the processor may obtain a surface roughness value of the object that is in contact with the display surface, by retrieving data corresponding to the measured second reflection pattern from a database to identify the hardness value that matches the second reflection pattern. Here, the hardness value may be stored in the database in association with data corresponding to the second reflection pattern.

The display device according to an embodiment of the present disclosure may detect the surface roughness of an object that is in contact with the display panel by adjusting a light emission pattern of the display panel, and detect the hardness of the object in contact by estimating a degree of deformation of the transparent layer of the display panel, thereby detecting various pieces of tactile information without a separate additional device.

FIG. 6 illustrates a method of operating a display device, according to an embodiment.

In detail, FIG. 6 is a diagram 600 for describing an operation, performed by the display device 100 of FIG. 1, of identifying a contact area between the display panel and an object.

Referring to FIG. 6, the operation, performed by the processor of the display device, of identifying a contact area may include operations 611, 613, and 615.

In operation 611, the processor may identify whether the amount of light received in a sub-region included in the display panel is less than a threshold value.

In an embodiment, when the amount of light received in the sub-region included in the display panel is less than the threshold value, the processor may determine that the amount of received light has temporarily decreased due to the contact between the display panel and the object, and thus perform operation 613.

In an embodiment, when the amount of light received in the sub-region included in the display panel is greater than or equal to the threshold value, the processor may determine that no contact has occurred between the display panel and an object, and thus the amount of received light is greater than or equal to the threshold value, and thus perform operation 615.

In operation 613, the processor may identify the contact area between the display panel and the object.

In an embodiment, when the amount of light received in the sub-region included in the display panel is less than the threshold value, the processor may identify the sub-region included in the display panel, as the contact area between the display panel and the object.

In operation 615, the processor may identify the sub-region as a non-contact area between the display panel and an object.

In an embodiment, when the amount of light received in the sub-region included in the display panel is greater than or equal to the threshold value, the processor may identify the sub-region included in the display panel, as a non-contact area between the display panel and an object.

FIG. 7 is a diagram illustrating an operation of changing a light emission pattern, according to an embodiment.

In detail, FIG. 7 is a diagram 700 for describing an operation, performed by the display device 100 of FIG. 1, of changing a light emission pattern.

Referring to FIG. 7, the display panel of the display device may include a contact area 713 between the display panel and an object, and non-contact areas 711 and 715.

In an embodiment, the processor may identify the contact area 713 between the display panel and the object, based on the embodiment described above with reference to FIG. 6.

In an embodiment, when the contact area 713 between the display panel and the object is identified, the processor may change light emission patterns of pixels included in the contact area 713.

In an embodiment, the processor may change the light emission patterns based on at least one of a difference in wavelength between lights emitted from the pixels included in the contact area, the reflectivity of the transparent layer of the display panel, or a resolution required to measure surface roughness.

In an embodiment, the processor may change the light emission patterns by changing the type of a light emission color, a light emission shape, a light emission period, and a light emission direction of the pixels included in the contact area between the display panel and the object.

In an embodiment, the processor may change the light emission patterns of the pixels included in the contact area, such that a difference in wavelength between lights emitted from the pixels included in the contact area is greater than or equal to a threshold value.

For example, the processor may change the light emission patterns to first light emission patterns such that pixels in a first contact area 731-1 emit red light and pixels in a second contact area 731-2 emit blue light, such that the difference in wavelength between lights emitted from the pixels is greater than or equal to the threshold value.

In an embodiment, the processor may change the light emission patterns of the pixels included in the contact area such that the light emission colors of the pixels included in the contact area are changed every predetermined period (or rotation cycle).

For example, the processor may change the light emission patterns to second light emission patterns such that the light emission colors emitted from the pixels included in a first contact area 733-1 to a third contact area 733-3 rotate counterclockwise (or clockwise) by repeating three cycles.

For example, the processor may be configured to cause the pixels in the first contact area 733-1 to emit red light, the pixels in the second contact area 733-2 to emit blue light, and the pixels in the third contact area 733-3 to emit green light during a first cycle, based on the second light emission patterns. The processor may be configured to cause the pixels in the first contact area 733-1 to emit blue light, the pixels in the second contact area 733-2 to emit green light, and the pixels in the third contact area 733-3 to emit red light during a second cycle, based on the second light emission patterns. The processor may be configured to cause the pixels in the first contact area 733-1 to emit green light, the pixels in the second contact area 733-2 to emit red light, and the pixels in the third contact area 733-3 to emit blue light during a third cycle, based on the second light emission patterns.

In an embodiment, the processor may measure a reflection pattern of light emitted from the pixels included in the contact area and then reflected from the contact surface with the object, based on the changed light emission patterns.

In an embodiment, the processor may detect the surface roughness of the object that is in contact with the display surface, by inputting the measured reflection pattern into a predetermined algorithm or searching a database to calculate a surface roughness value corresponding to the reflection pattern.

The processor of the display device according to an embodiment of the present disclosure may provide a display device capable of, when contact with an object is detected, changing light emission patterns of pixels in a contact area, measuring a reflection pattern according to the changed light emission patterns, and detecting the surface roughness of the object in contact based on the measured reflection pattern.

The changed light emission patterns in the contact area with the object is described above based on the first light emission patterns and the second light emission patterns with reference to FIG. 7, but are not limited thereto, and may be changed to various light emission patterns depending on changes in the type of a light emission color, a light emission shape, a light emission period, and a light emission direction of the pixels included in the contact area.

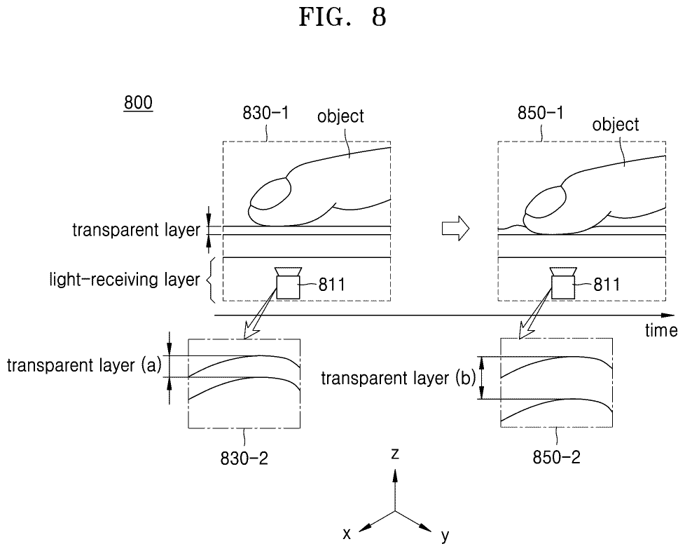

FIG. 8 is a diagram illustrating an operation of estimating a degree of deformation of a display panel, according to an embodiment.

In detail, FIG. 8 a diagram 800 for describing an operation, performed by the display device 100 of FIG. 1, of estimating a degree of deformation of the display panel.

Referring to FIG. 8, the display panel of the display device may include a transparent layer and a light-receiving layer. Here, a first shape 830-2 and a second shape 850-2 are plan views of an object that is in contact with the display panel, as viewed in the z-axis direction from a photodetector of the light-receiving layer of the display panel.

In an embodiment, the light-receiving layer of the display panel may include a photodetector 811 for estimating a degree of deformation of the transparent layer due to contact between the display panel and an object. Here, the photodetector 811 may include a charge-coupled device (CCD) camera or an image sensor as a module for detecting light within the display panel or measuring the amount of received light or a reflection pattern.

In an embodiment, the processor may use the photodetector 811 to measure a deformation time period, a deformation recovery time period, and a deformation over time of the display panel (e.g., the transparent layer) due to contact between the display panel (e.g., the transparent layer) and an object.

Here, the deformation time period of the transparent layer may refer to the time period from the start of the contact between the display panel and the object to the time point at which the object may no longer be compressed due to the contact. The deformation recovery time period of the transparent layer may refer to the time period from the time point at which the object may no longer be compressed due to the contact between the display panel and the object, to the time point at which the object recovers its original state, and the degree of deformation of the transparent layer may refer to the area deformed due to the contact between the display panel and the object.

For example, a first state 830-1 is a state immediately before the object comes into contact with the display panel (e.g., the transparent layer), and the shape captured by the photodetector 811 may correspond to the first shape 830-2. Here, the width of the transparent layer before deformation due to the contact with the object may be ‘a’ (a>0).

For example, a second state 850-1 is a state in which the object is in contact with the display panel (e.g., the transparent layer), and the shape captured by the photodetector 811 may correspond to the second shape 850-2. Here, the width of the transparent layer after deformation due to the contact with the object may be ‘b’ (b>a>0).

In an embodiment, the processor may estimate the degree of deformation (e.g., a deformation indentation or a deformation area) of the transparent layer caused by the contact between the display panel and the object, based on the deformation time period, the deformation recovery time period, and the width of a deformation over time of the transparent layer.

In an embodiment, the processor may measure a reflection pattern of light emitted from the pixels included in the contact area and then reflected from the contact surface with the object, based on the estimated degree of deformation of the transparent layer.

In an embodiment, the processor may detect the hardness of the object that is in contact with the display surface, by inputting the measured reflection pattern into a predetermined algorithm or searching a database to calculate a hardness value corresponding to the reflection pattern.

The processor of the display device according to an embodiment of the present disclosure may provide a display device capable of, when contact with an object is detected, estimating a degree of deformation of the transparent layer due to the contact, and detecting the hardness of the object in contact based on the estimated degree of deformation of the transparent layer.

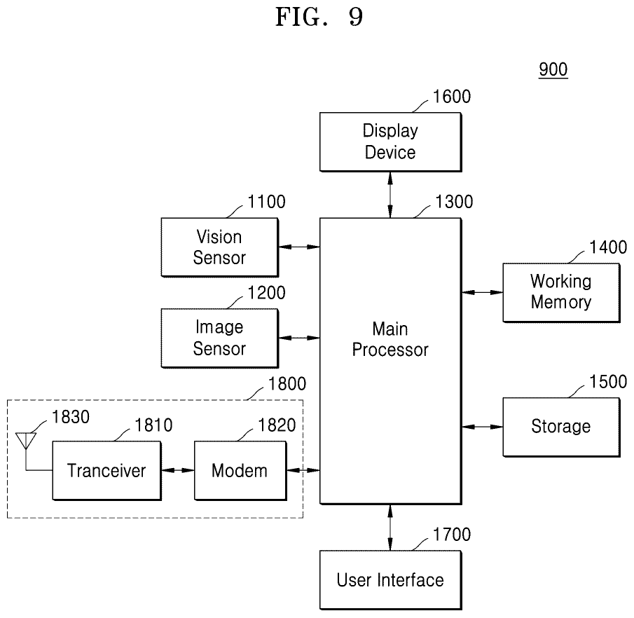

FIG. 9 is a block diagram 900 illustrating an electronic device including a processor, according to an embodiment.

Referring to FIG. 9, an electronic device 1000 may include a vision sensor 1100, an image sensor 1200, a main processor 1300, a working memory 1400, a storage 1500, a display device 1600, a user interface 1700, and a communication unit 1800. The present disclosure is not limited thereto, and the electronic device 1000 may be implemented such that at least some of the above-described components are omitted or separate components are added.

The display device 100 and the processor described above with reference to FIGS. 1 to 8 may be applied to the display device 1600 and the main processor 1300, respectively.

The vision sensor 1100 may sense an object to generate event signals and transmit the generated event signals to the main processor 1300. In FIGS. 1 to 8B, the vision sensor 1100 may be interpreted as a component included in the image sensor 1200, but is not limited thereto, and the vision sensor 1100 according to an embodiment of the present disclosure may function or operate as an independent sensor in the electronic device 1000, with only the vision sensor 100.

The image sensor 1200 may generate image data, for example, raw image data, based on a received optical signal, and provide the image data to the main processor 1300.

The main processor 1300 may control the overall operation of the electronic device 1000, and may identify whether there is contact between the display panel and an object, or identify a contact area.

The main processor 1300 may change light emission patterns of pixels included in the contact area between the display panel and the object, and measure a first reflection pattern of lights reflected from the contact surface between the display panel and the object, according to the changed light emission patterns.

The main processor 1300 may estimate a degree of deformation of the transparent layer based on a deformation time period, a deformation recovery time period, and a deformation over time of the transparent layer of the display panel that is deformed due to the contact between the display panel and the object, and measure a second reflection pattern of lights reflected from the contact surface between the display panel and the object, according to the degree of deformation of the transparent layer.

The main processor 1300 may detect the surface roughness of the object in contact, based on the measured second reflection pattern.

The working memory 1400 may store data used for an operation of the electronic device 1000. For example, the working memory 1400 may temporarily store packets or frames processed by the main processor 1300. For example, the working memory 1400 may temporarily store a first reflection pattern of lights reflected from a contact surface between the display panel and an object according to changed light emission patterns, or a second reflection pattern of lights reflected from the contact surface between the display panel and the object according to a degree of deformation of the transparent layer of the display panel.

For example, the working memory 1400 may include a volatile memory such as dynamic random-access memory (DRAM), synchronous DRAM (SDRAM), or the like, and/or a non-volatile memory such as phase-change RAM (PRAM), magnetoresistive RAM (MRAM), resistive RAM (ReRAM), or ferroelectric RAM (FRAM).

The storage 1500 may store data requested to be stored from the main processor 1300 or other components. The storage 1500 may include a nonvolatile memory such as flash memory, PRAM, MRAM, ReRAM, or FRAM. The storage 1500 may store an algorithm or a database for detecting the surface roughness or hardness of an object.

The display device 1600 may include a display panel, a DDI, and a display serial interface (DSI). For example, the display panel may be implemented as various devices such as a liquid-crystal display (LCD) device, a light-emitting diode (LED) display device, an organic LED (OLED) display device, or an active-matrix OLED (AMOLED) display device. The DDI may include a timing controller, a source driver, and the like required to drive the display panel. A DSI host embedded in the main processor 1300 may perform serial communication with the display panel via the DSI.

The user interface 1700 may include at least one of input interfaces such as a keyboard, a mouse, a keypad, a button, a touch panel, a touch screen, a touch pad, a touch ball, a gyroscope sensor, a vibration sensor, or an acceleration sensor.

The communication unit 1800 may exchange signals with an external device/system through an antenna 1830. A transceiver 1810 and a modulator-demodulator (MODEM) 1820 of the communication unit 1800 may process signals exchanged with external devices/systems according to wireless communication protocols such as Long-Term Evolution (LTE), Worldwide Interoperability for Microwave Access (WiMAX), Global System for Mobile communications (GSM), code-division multiple access (CDMA), Bluetooth, near-field communication (NFC), Wireless Fidelity (Wi-Fi), or radio-frequency identification (RFID).

The components of the electronic device 1000, for example, the vision sensor 1100, the image sensor 1200, the main processor 1200, the working memory 1400, the storage 1500, the display device 1600, the user interface 1700, and the communication unit 1800, may exchange data based on one or more of various interface protocols, such as Universal Serial Bus (USB), Small Computer System Interface (SCSI), Mobile Industry Processor Interface (MIPI), Inter-Integrated Circuit (I2C), Peripheral Component Interconnect Express (PCIe), Mobile PCIe (M-PCIe), Advanced Technology Attachment (ATA), Parallel ATA (PATA), Serial ATA (SATA), Serial Attached SCSI (SAS), Integrated Drive Electronics (IDE), Enhanced IDE (EIDE), Nonvolatile Memory Express (NVMe), or Universal Flash Storage (UFS).

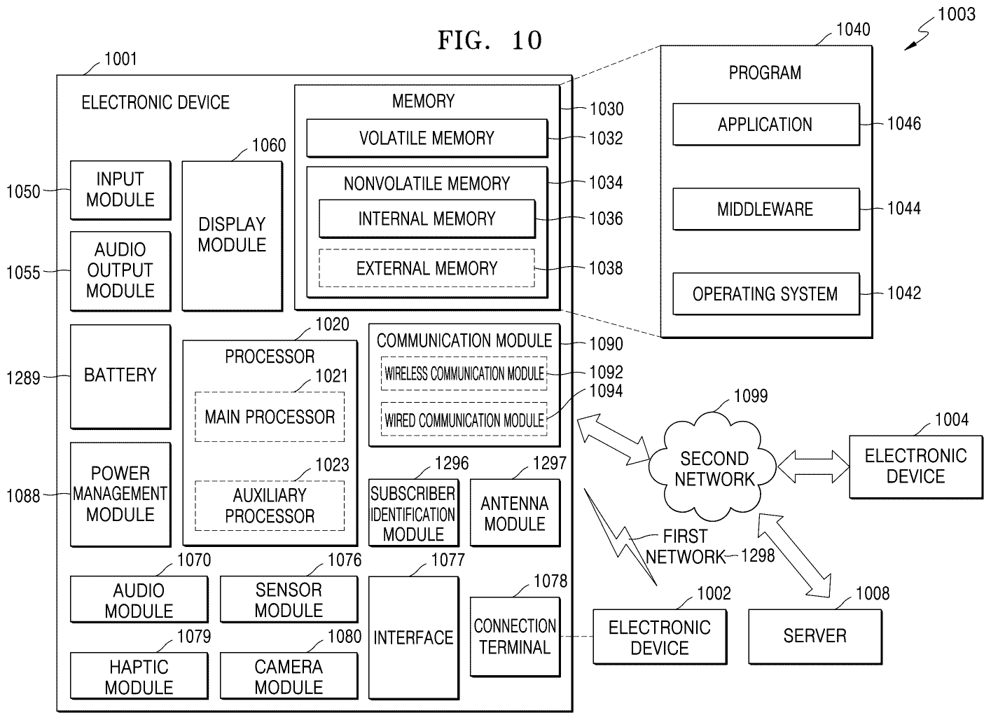

FIG. 10 is a block diagram illustrating an electronic device including a display module, according to an embodiment.

Referring to FIG. 10, in a network environment 1003, an electronic device 1001 may communicate with an electronic device 1002 through a first network 1098 (e.g., a short-range wireless communication network), or may communicate with an electronic device 1004 or a server 1008 through a second network 1099 (e.g., a long-range wireless communication network). According to an embodiment, the electronic device 1001 may communicate with the electronic device 1004 via the server 1008. According to an embodiment, the electronic device 1001 may include a processor 1020, a memory 1030, an input module 1050, an audio output module 1055, a display module 1060, an audio module 1070, a sensor module 1076, an interface 1077, a connection terminal 1078, a haptic module 1079, a camera module 1080, a power management module 1088, a battery 1089, a communication module 1090, a subscriber identification module 1096, or an antenna module 1097. In some embodiments, at least one of these components (e.g., the connection terminal 1078) may be omitted from the electronic device 1001, or one or more other components may be added to the electronic device 1001. In some embodiments, some of these components (e.g., the sensor module 1076, the camera module 1080, or the antenna module 1097) may be integrated into one component (e.g., the display module 1060).

The processor 1020 may execute, for example, software (e.g., a program 1040) to control at least one of other components (e.g., a hardware or software component) of the electronic device 1001, which is connected to the processor 1020, and perform various types of data processing or computation. According to an embodiment, as at least part of the data processing or computation, the processor 1020 may store a command or data received from another component (e.g., the sensor module 1076 or the communication module 1090) in a volatile memory 1032, process the command or data stored in the volatile memory 1032, and store resulting data in a nonvolatile memory 1034. According to an embodiment, the processor 1020 may include a main processor 1021 (e.g., a central processing unit or an application processor) or an auxiliary processor 1023 (e.g., a graphics processing unit, a neural processing unit (NPU), an image signal processor, a sensor hub processor, or a communication processor) that may be operated together with or independently of the main processor 1021. For example, in a case in which the electronic device 1001 includes the main processor 1021 and the auxiliary processor 1023, the auxiliary processor 1023 may use less power than the main processor 1021 or may be set to be specialized for a designated function. The auxiliary processor 1023 may be implemented separately from or as a part of the main processor 1021.

For example, the processor 1020 may obtain a surface roughness value of an object that is in contact with a display panel, by changing a light emission pattern of the display panel and measuring a reflection pattern of light reflected from a contact surface between the display panel and the object.

For example, the processor 1020 may obtain a hardness value of the object in contact by estimating a degree of deformation of the display panel due to the contact between the display panel and the object, and measuring a reflection pattern of lights reflected from the contact surface between the display panel and the object, based on the degree of deformation of the display panel.

For example, the auxiliary processor 1023 may control at least some of functions or states related to at least one component (e.g., the display module 1060, the sensor module 1076, or the communication module 1090) among the components of the electronic device 1001, on behalf of the main processor 1021 while the main processor 1021 is in an inactive (e.g., sleep) state, or together with the main processor 1021 while the main processor 1021 is in an active (e.g., application execution) state. According to an embodiment, the auxiliary processor 1023 (e.g., an image signal processor or a communication processor) may be implemented as a portion of another component (e.g., the camera module 1080 or the communication module 1090) functionally associated with the auxiliary processor 1023. According to an embodiment, the auxiliary processor 1023 (e.g., a neural network processing device) may include a hardware structure specialized for processing of an artificial intelligence model. The artificial intelligence model may be generated through machine learning. For example, such learning may be performed, by the electronic device 1001 in which artificial intelligence is performed, or may be performed by a separate server (e.g., the server 1008). Examples of learning algorithms may include, for example, supervised learning, unsupervised learning, semi-supervised learning, and reinforcement learning, but are not limited thereto. The artificial intelligence model may include a plurality of neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof, but is not limited thereto. The artificial intelligence model may additionally or alternatively include a software structure in addition to the hardware structure.

The memory 1030 may store various pieces of data to be used by at least one component (e.g., the processor 1020 or the sensor module 1076) in the electronic device 1001. The data may include, for example, software (e.g., the program 1040) and input data or output data related to a command associated with the software. The memory 1030 may include the volatile memory 1032 and the nonvolatile memory 1034.

The program 1040 may be stored in the memory 1030 as software, and may include, for example, an operating system 1042, middleware 1044, or an application 1046.

The input module 1050 may receive, from the outside (e.g., the user) of the electronic device 1001, a command or data to be used by a component (e.g., the processor 1020) of the electronic device 1001. The input module 1050 may include, for example, a microphone, a mouse, a keyboard, a key (e.g., a button), or a digital pen (e.g., a stylus pen).

The audio output module 1055 may output an audio signal to the outside of the electronic device 1001. The audio output module 1055 may include, for example, a speaker or a receiver. The speaker may be used for general purposes, such as reproducing multimedia or record. The receiver may be used to receive an incoming call. According to an embodiment, the receiver may be implemented separately from, or as part of the speaker.

The display module 1060 may visually provide information to the outside (e.g., the user) of the electronic device 1001. The display module 1060 may include, for example, a display, a hologram device, or a projector, and a control circuit for controlling the corresponding device. According to an embodiment, the display module 1060 may include a touch sensor configured to detect a touch, or a pressure sensor configured to measure the intensity of force generated by the touch.

According to an embodiment, the display module 1060 may detect the surface roughness or hardness of an object that is in in contact with the display module 1060, while simultaneously displaying an image.

The audio module 1070 may convert a sound into an electrical signal or vice versa. According to an embodiment, the audio module 1070 may obtain a sound through the input module 1050 or output a sound through the audio output module 1055 or an external electronic device (e.g., the electronic device 1002 (e.g., a speaker or headphones)) directly or wirelessly connected to the electronic device 1001.

The sensor module 1076 may detect an operating state (e.g., power or a temperature) of the electronic device 1001 or an external environment state (e.g., a user state) and generate an electrical signal or a data value corresponding to the detected state. According to an embodiment, the sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more designated protocols, which may be used to directly or wirelessly connect the electronic device 1010 to an external electronic device (e.g., the electronic device 1002). According to an embodiment, the interface 1077 may include, for example, a high-definition multimedia interface (HDMI), a USB interface, a secure digital (SD) card interface, or an audio interface.

The connection terminal 1078 may include a connector through which the electronic device 1001 may be physically connected to an external electronic device (e.g., the electronic device 1002). According to an embodiment, the connection terminal 1078 may include, for example, an HDMI connector, a USB connector, an SD card connector, or an audio connector (e.g., a headphone connector).

The haptic module 1079 may convert an electrical signal into a mechanical stimulus (e.g., vibration or movement) or an electrical stimulus that may be recognized by a user through his/her tactile or motion sensation. According to an embodiment, the haptic module 1079 may include, for example, a motor, a piezoelectric device, or an electrical stimulation device.

The camera module 1080 may capture a still image or a moving image. According to an embodiment, the camera module 1080 may include one or more lenses, image sensors, image signal processors, or flashes.

The power management module 1088 may manage power supplied to the electronic device 1001. According to an embodiment, the power management module 1088 may be implemented, for example, as at least part of a PMIC.

The battery 1089 may supply power to at least one component of the electronic device 1001. According to an embodiment, the battery 1089 may include, for example, a non-rechargeable primary cell, a rechargeable secondary cell, or a fuel cell.

The communication module 1090 may establish a direct (e.g., wired) communication channel or a wireless communication channel between the electronic device 1001 and an external electronic device (e.g., the electronic device 1002, the electronic device 1004, or the server 1008) and support communication through the established communication channel. The communication module 1090 may include one or more communication processors operating independently from the processor 1020 (e.g., an AP) and supporting direct (e.g., wired) communication or wireless communication. According to an embodiment, the communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication module). The corresponding communication module among these communication modules may communicate with the external electronic device 1004 through the first network 1098 (e.g., a short-range communication network such as Bluetooth, Wi-Fi Direct, or Infrared Data Association (IrDA)) or the second network 1099 (e.g., a long-range communication network such as a legacy cellular network, a 5G network, a next-generation communication network, the Internet, or a computer network (e.g., a LAN or wide area network (WAN)). These types of communication modules may be integrated into one component (e.g., a single chip) or implemented by a plurality of separate components (e.g., a plurality of chips). The wireless communication module 1092 may identify or authenticate the electronic device 1001 within a communication network such as the first network 1098 and/or the second network 1099 by using subscriber information (e.g., an international mobile subscriber identifier (IMSI)) stored in the subscriber identification module 1096.

The wireless communication module 1092 may support 5G network and next-generation communication technology after 4G network, for example, new radio (NR) access technology. The NR access technology may support high-speed transmission of high-capacity data (enhanced mobile broadband (eMBB)), terminal power minimization and multiple terminal accesses (massive machine-type communications (mMTC)), or ultra-reliable low latency communications (URLLC). The wireless communication module 1092 may support a high-frequency band (e.g., a mmWave band), for example, to achieve a high data transmission rate. The wireless communication module 1092 may support various techniques for securing performance in a high-frequency band, for example, beamforming, massive multiple-input and multiple-output (MIMO), full dimensional MIMO (FD-MIMO), array antenna, analog beamforming, or large-scale antenna. The wireless communication module 1092 may support various requirements specified in the electronic device 1001, an external electronic device (e.g., the electronic device 1004), or a network system (e.g., the second network 1099). According to an embodiment, the wireless communication module 1092 may support a peak data rate (e.g., 20 Gbps or greater) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 1097 may transmit a signal or power to the outside (e.g., an external electronic device) or receive a signal or power from the outside. According to an embodiment, the antenna module 1097 may include an antenna including a radiator including a conductive material or a conductive pattern formed on a substrate (e.g., a printed circuit board (PCB)). According to an embodiment, the antenna module 1097 may include a plurality of antennas (e.g., an array antenna). In this case, at least one antenna suitable for a communication scheme used in a communication network such as the first network 1098 or the second network 1099 may be selected from the plurality of antennas by, for example, the communication module 1090. The signal or the power may be transmitted or received between the communication module 1090 and an external electronic device through the selected at least one antenna. According to some embodiments, a component (e.g., a radio-frequency integrated circuit (RFIC)) other than the radiator may be additionally formed as part of the antenna module 1097.

According to various embodiments, the antenna module 1097 may form a mmWave antenna module. According to an embodiment, the mmWave antenna module may include a PCB, a RFIC arranged on a first surface (e.g., the bottom surface) of the PCB, or adjacent to the first surface and capable of supporting a specified high-frequency band (e.g., a mmWave band), and a plurality of antennas (e.g., an array antenna) arranged on a second surface (e.g., the top or a side surface) of the PCB, or adjacent to the second surface and capable of transmitting or receiving signals of the specified high-frequency band.

At least some of the components may be connected to each other in a peripheral device communication scheme (e.g., a bus, a general-purpose input and output (GPIO), a serial peripheral interface (SPI), or a mobile industry processor interface (MIPI)) and exchange a signal (e.g., a command or data) with each other.

According to an embodiment, a command or data may be transmitted or received between the electronic device 1001 and the external electronic device 1004 via the server 1008 connected over the second network 1099. Each of the external electronic devices 1002 and 1004 may be of the same type as, or a different type from the electronic device 1001. According to an embodiment, all or some of operations executed by the electronic device 1001 may be executed by at least one of the electronic devices 1002 and 1004 and the server 1008. For example, when the electronic device 1001 is supposed to perform a certain function or service automatically or in response to a request from the user or another device, the electronic device 1001 may request one or more external electronic devices to perform at least part of the function or service, additionally or instead of autonomously executing the function or service. The one or more external electronic devices having received the request may execute the at least part of the requested functions or services or an additional function or service related to the request, and transmit a result of the execution to the electronic device 1001. The electronic device 1001 may process the result as it is or additionally and provide the processing result as at least part of a response to the request. To this end, for example, cloud computing, distributed computing, mobile edge computing (MEC), or client-server computing technology may be used. The electronic device 1001 may provide an ultra-low latency service by using, for example, distributed computing or MEC. In another embodiment, the external electronic device 1004 may include an Internet-of-Things (IoT) device. The server 1008 may be an intelligent server using machine learning and/or a neural network. According to an embodiment, the external electronic device 1004 or the server 1008 may be included in the second network 1099. The electronic device 1001 may be applied to intelligent services (e.g., smart homes, smart cities, smart cars, or health care) based on 5G communication technologies and IoT-related technologies.

The memory 1030 may include tasks for performing machine learning, neural network algorithms for performing the tasks, target functions, and input data or output data for commands related thereto.

The memory 1030 may store, for example, instructions or data related to at least one of the other components of the electronic device 1001. The instructions may be executed by at least one of the processor or the image processing module. The instructions may include at least one of a collection instruction related to collecting a candidate image, a display instruction related to displaying a candidate image, an analysis instruction related to analyzing a selected candidate image, or a provision instruction related to generating and providing at least one recommended image based on the analysis result, or a provision instruction related to providing the selected image.

The collection instruction may be, for example, an instruction used in collecting a candidate image using at least one of the communication module 1090 or the camera. For example, the collection instruction may include an instruction for accessing the server 1008 or the external electronic device 1002 or 1004 according to a scheduled setting or a user input, an instruction related to receiving a candidate image list of the server 1008 or the external electronic device accessed, an instruction for requesting and collecting the selected candidate image according to a user input, and the like. The analysis instruction may include, for example, a region of interest (ROI)-centered image analysis instruction, a user context-based image analysis instruction, and the like. At least one instruction included in the above-described analysis instruction may be used to candidate image application according to a setting or a user input. The provision instruction may include at least one of an instruction for recommending an ROI-centered image and providing a preview, an instruction for recommending an image based on a screen property to be set, an instruction for recommending by exceeding an actual image, an instruction for displaying a margin when the margin is included in the modified image, an instruction for recommending an image based on a screen type of the electronic device, and an instruction for applying a designated filter in image recommendation.

The memory 1030 may store an analysis database, and an image database. The analysis database may store at least one instruction or at least one program related to the candidate image analysis. The analysis database may store, for example, an analysis algorithm for distinguishing and classifying candidate images for each object. The analysis algorithm may distinguish, for example, a background object, a person object, a thing object, and an animal object of the candidate image. In this regard, the analysis database may store texture information or feature point information for distinguishing a person, a thing, an animal, and the like. Also, the analysis database may store feature point information or texture information for distinguishing a human face, an animal face, and the like. The image database may store at least one candidate image. For example, the image database may store at least one candidate image applied to a lock screen, a home screen, a designated application execution screen, and the like. The candidate image stored in the image database may be collected through a camera, or may be received from an external electronic device or a server as described above. According to various embodiments, the image database may store a recommended image generated based on a particular candidate image. The image database may store device information about the electronic device 1001 or the external electronic device 1002. In addition, the image database may store information about the selected images applied to the electronic device 1001 or the external electronic device 1002.

A device and a method according to embodiments of the present disclosure may provide a display device capable of detecting the surface roughness or hardness of an object and also having an image display function, and a method of operating the display device.

According to an embodiment, a display device includes: a display panel including a plurality of pixels; a memory storing one or more instructions; and one or more processors, wherein the one or more processors are configured to execute the one or more instructions to change light emission patterns of pixels included in a contact area between the display panel and an object, measure a first reflection pattern that is reflected from the contact area according to the changed light emission patterns, detect surface roughness of the object based on the first reflection pattern, estimate a degree of deformation of a transparent layer of the display panel that is caused by the contact between the display panel and the object, measure a second reflection pattern that is reflected from the contact area, based on the degree of deformation of the transparent layer, and detect hardness of the object based on the second reflection pattern.

According to an embodiment, the one or more processors may, based on an amount of light received in at least one sub-region included in the display panel being less than a threshold value, identify the at least one sub-region included in the display panel, as the contact area between the display panel and the object.

In an embodiment, the one or more processors may be configured to determine the light emission patterns based on at least one of a difference in wavelength between lights emitted from the pixels included in the contact area, the reflectivity of the transparent layer, or a resolution required for measuring the surface roughness.

According to an embodiment, the one or more processors may be configured to change the light emission patterns by changing a type of a light emission color, a light emission shape, a light emission period, and a light emission direction of the pixels included in the contact area.

According to an embodiment, the one or more processors may be configured to measure a deformation time period of the transparent layer and a deformation recovery time period of the transparent layer, and estimate the degree of deformation of the transparent layer based on the measured deformation time period of the transparent layer, the measured deformation recovery time period of the transparent layer, and a deformation over time of the transparent layer.

According to an embodiment, the first reflection pattern and the second reflection pattern may refer to reflection patterns of lights reflected from a contact surface between the display panel and the object among lights emitted from pixels included in the contact area.

According to an embodiment, the display panel may include a light-receiving layer, a light-emitting layer, and a transparent layer that are stacked in a vertical direction, the light-receiving layer may include a photodetector configured to measure the first reflection pattern or the second reflection pattern, and the light-emitting layer may be arranged on the light-receiving layer and may include the plurality of pixels.

According to an embodiment, the transparent layer may be arranged on the light-emitting layer in the display panel and may be implemented with an elastic material.

According to an embodiment, a region for detection of the surface roughness and a region for detection of the hardness may overlap with each other in at least one of regions respectively allocated to the plurality of pixels.

According to an embodiment, the region for detection of the surface roughness may include a first region included in each of the plurality of pixels, the region for detection of the hardness may include a second area included in each of the plurality of pixels, and the first region and the second region may refer to different regions.

In an embodiment, a method of operating a display device includes changing light emission patterns of pixels included in a contact area between a display panel and an object, measuring a first reflection pattern that is reflected from the contact area according to the changed light emission patterns, detecting surface roughness of the object based on the first reflection pattern, estimating a degree of deformation of a transparent layer of the display panel that is caused by the contact between the display panel and the object, measuring a second reflection pattern that is reflected from the contact area, based on the degree of deformation of the transparent layer, and detecting hardness of the object based on the second reflection pattern, wherein the display panel includes a plurality of pixels.

In an embodiment, the method may further include, based on an amount of light received in at least one sub-region included in the display panel being less than a threshold value, identifying the at least one sub-region included in the display panel, as the contact area between the display panel and the object.

According to an embodiment, the method may further include determining the light emission patterns based on at least one of a difference in wavelength between lights emitted from the pixels included in the contact area, reflectivity of the transparent layer, or a resolution required to measure the surface roughness.

According to an embodiment, the changing of the light emission patterns may include changing the light emission patterns by changing a type of a light emission color, a light emission shape, a light emission period, and a light emission direction of the pixels included in the contact area.

According to an embodiment, the method may further include measuring a deformation time period of the transparent layer and a deformation recovery time period of the transparent layer, and estimating the degree of deformation of the transparent layer based on the measured deformation time period of the transparent layer, the measured deformation recovery time period of the transparent layer, and a deformation over time of the transparent layer.

According to an embodiment, the first reflection pattern and the second reflection pattern may refer to reflection patterns of lights reflected from a contact surface between the display panel and the object among lights emitted from pixels included in the contact area.

According to an embodiment, the display panel may include a light-receiving layer, a light-emitting layer, and a transparent layer that are stacked in a vertical direction, the light-receiving layer may include a photodetector configured to measure the first reflection pattern or the second reflection pattern, the light-emitting layer may be arranged on the light-receiving layer and includes the plurality of pixels, and the transparent layer may be arranged on the light-emitting layer and may include an elastic material.

According to an embodiment, a region for detection of the surface roughness and a region for detection of the hardness may overlap with each other in a region included in each of the plurality of pixels.

According to an embodiment, the region for detection of the surface roughness may include a first region included in each of the plurality of pixels, the region for detection of the hardness may include a second area included in each of the plurality of pixels, and the first region and the second region may refer to different regions.

The method of operating a display device according to an embodiment of the disclosure may be embodied as program instructions executable by various computer devices, and recorded on a computer-readable medium. The computer-readable medium may include program instructions, data files, data structures, or the like separately or in combinations.

The computer-readable medium may be any available medium which is accessible by a computer, and may include a volatile or non-volatile medium and a detachable and non-detachable medium. Also, the computer-readable medium may include a computer storage medium and a communication medium. The computer storage media include both volatile and non-volatile, detachable and non-detachable media implemented in any method or technique for storing information such as computer readable instructions, data structures, program modules or other data. The communication medium may typically include computer-readable instructions, data structures, or other data of a modulated data signal such as program modules.

In addition, the computer-readable storage medium may be provided in the form of a non-transitory storage medium. Here, the term ‘non-transitory storage medium’ refers to a tangible device and does not include a signal (e.g., an electromagnetic wave), and the term ‘non-transitory storage medium’ does not distinguish between a case where data is stored in a storage medium semi-permanently and a case where data is stored temporarily. For example, the ‘non-transitory storage medium’ may include a buffer in which data is temporarily stored.

The program instructions to be recorded on the medium may be specially designed and configured for the present disclosure or may be well-known to and be usable by those skill in the art of computer software. Examples of the computer-readable recording medium include magnetic media such as hard disks, floppy disks, or magnetic tapes, optical media such as a compact disc read-only memory (CD-ROM) or a digital video disc (DVD), magneto-optical media such as a floptical disk, and hardware devices such as ROM, random-access memory (RAM), or flash memory, which are specially configured to store and execute program commands. Examples of program commands include not only machine code, such as code made by a compiler, but also high-level language code that is executable by a computer by using an interpreter or the like.

In addition, at least one of the method of operating a display device or the method of operating an electronic device according to the disclosed embodiments may be included in a computer program product and provided. The computer program product may be traded as commodities between sellers and buyers. The computer program product may be distributed in the form of a machine-readable storage medium (e.g., a CD-ROM), or may be distributed online (e.g., downloaded or uploaded) through an application store or directly between two user devices (e.g., smart phones). In a case of online distribution, at least a portion of the computer program product (e.g., a downloadable app) may be temporarily stored in a machine-readable storage medium such as a manufacturer's server, an application store's server, or a memory of a relay server.

The computer program product may include a S/W program and a computer-readable recording medium storing the S/W program. For example, the computer program product may include a product in the form of a S/W program electronically distributed (e.g., a downloadable application) through a manufacturer of an electronic device or an electronic market (e.g., Google Play Store, App Store). For electronic distribution, at least part of the S/W program may be stored in a storage medium or temporarily generated. In this case, the storage medium may be a storage medium of a server of the manufacturer or a server of the electronic market, or a relay server that temporarily stores the S/W program.

The computer program product may include a storage medium of a server or a storage medium of a client device, in a system consisting of the server and the client device. Alternatively, when there is a third device (e.g., a smart phone) communicatively connected to the server or the client device, the computer program product may include a storage medium of the third device. Alternatively, the computer program product may include a software program, which is transmitted from the server to the client device or the third device or transmitted from the third device to the client device.

In this case, one of the server, the client device, and the third device may execute the computer program product to perform the method according to the embodiments of the disclosure. Alternatively, two or more of the server, the client device, and the third device may execute the computer program product to execute the method according to the disclosed embodiments in a distributed manner.

For example, the server (e.g., a cloud server, an artificial intelligence server) may execute the computer program product stored in the server to control the client device communicatively connected to the server to perform the method according to the disclosed embodiments.

While the present disclosure have been particularly shown and described, it will be understood by one of ordinary skill in the art that various changes in form and details may be made therein without departing from the spirit and scope of the present disclosure. Therefore, it should be understood that the above-described embodiments are exemplary in all respects and do not limit the scope of the present disclosure. For example, each element described in a single type may be executed in a distributed manner, and elements described distributed may also be executed in an integrated form.

The scope of the present disclosure is not defined by the detailed description of the present disclosure but by the following claims, and all modifications or alternatives derived from the scope and spirit of the claims and equivalents thereof fall within the scope of the present disclosure.

Although embodiments have been described above in detail, the scope of the present disclosure is not limited thereto, and various modifications and alterations by those of skill in the art using the basic concept of the present disclosure defined in the following claims also fall within the scope of the present disclosure.

What is claimed is:

1. A display device comprising:
a display panel comprising a plurality of pixels;
a memory storing one or more instructions; and
one or more processors configured to execute the one or more instructions to:
change light emission patterns of pixels included in a contact area at which an object contacts the display panel,
measure a first reflection pattern at the contact area according to the changed light emission patterns,
detect a surface roughness of the object based on the first reflection pattern,
estimate a degree of deformation of a transparent layer of the display panel corresponding to the contact between the display panel and the object,
measure a second reflection pattern at the contact area, based on the degree of deformation of the transparent layer, and
detect a hardness of the object based on the second reflection pattern.

2. The display device of claim 1, wherein the one or more processors are further configured to execute the one or more instructions to:
based on an amount of light received in at least one sub-region of the display panel being less than a threshold value, identify the at least one sub-region of the display panel as the contact area at which the object contacts the display panel.

3. The display device of claim 1, wherein the one or more processors are further configured to execute the one or more instructions to:
determine the light emission patterns based on at least one of a difference in wavelength between lights emitted from the pixels included in the contact area, a reflectivity of the transparent layer, or a resolution to measure the surface roughness.

4. The display device of claim 1, wherein the changing the light emission patterns comprises:
changing at least one of a type of a light emission color, a light emission shape, a light emission period, or a light emission direction of the pixels included in the contact area.

5. The display device of claim 1, wherein the one or more processors are further configured to execute the one or more instructions to:
measure a deformation time period of the transparent layer and a deformation recovery time period of the transparent layer, and
estimate the degree of deformation of the transparent layer based on the measured deformation time period of the transparent layer, the measured deformation recovery time period of the transparent layer, and a deformation of the transparent layer over time.

6. The display device of claim 1, wherein the display panel comprises a light-receiving layer, a light-emitting layer, and the transparent layer stacked in a vertical direction,
wherein the light-receiving layer comprises a photodetector configured to measure the first reflection pattern or the second reflection pattern, and
wherein the light-emitting layer is provided on the light-receiving layer and comprises the plurality of pixels.

7. The display device of claim 1, wherein a region for detection of the surface roughness and a region for detection of the hardness overlap in at least one region among the plurality of pixels.

8. A method of operating a display device, the method comprising:
changing light emission patterns of pixels included in a contact area at which an object contacts a display panel of the display device, the display panel including a plurality of pixels;
measuring a first reflection pattern at the contact area according to the changed light emission patterns;
detecting a surface roughness of the object based on the first reflection pattern;
estimating a degree of deformation of a transparent layer of the display panel corresponding to the contact between the display panel and the object;
measuring a second reflection pattern at the contact area, based on the degree of deformation of the transparent layer; and
detecting a hardness of the object based on the second reflection pattern.

9. The method of claim 8, further comprising:
based on an amount of light received in at least one sub-region of the display panel being less than a threshold value, identifying the at least one sub-region of the display panel as the contact area at which the object contacts the display panel.

10. The method of claim 8, further comprising:
determining the light emission patterns based on at least one of a difference in wavelength between lights emitted from the pixels included in the contact area, a reflectivity of the transparent layer, or a resolution to measure the surface roughness.

11. The method of claim 8, wherein the changing the light emission patterns comprises:
changing at least one of a type of a light emission color, a light emission shape, a light emission period, or a light emission direction of the pixels included in the contact area.

12. The method of claim 8, further comprising:
measuring a deformation time period of the transparent layer and a deformation recovery time period of the transparent layer, and
estimating the degree of deformation of the transparent layer based on the measured deformation time period of the transparent layer, the measured deformation recovery time period of the transparent layer, and a deformation of the transparent layer over time.

13. The method of claim 8, wherein the display panel includes a light-receiving layer, a light-emitting layer, and the transparent layer stacked in a vertical direction,
wherein the light-receiving layer includes a photodetector configured to measure the first reflection pattern or the second reflection pattern,
wherein the light-emitting layer is provided on the light-receiving layer and includes the plurality of pixels, and
wherein the transparent layer is provided on the light-emitting layer and includes an elastic material.

14. The method of claim 8, wherein a region for detection of the surface roughness and a region for detection of the hardness overlap in at least one region among the plurality of pixels.

15. A computer-readable recording medium having recorded thereon a program for causing a computer to execute the method of claim 8.

16. The display device of claim 6, wherein the transparent layer is provided on the light-emitting layer and comprises an elastic material.
